(19) United States
(12) Patent Application Publication
(10) Pub. No.: US 2004/0012688 A1
(43) Pub. Date: Jan. 22, 2004

(54) Large area charge coupled device camera

(75) Inventors: Natale F. Tinnerino, Morgan Hill, CA (US); David Wen, Los Altos, CA (US); Edward Leon Guerrero, Union City, CA (US); Douglas Debs, Palo Alto, CA (US); Dan Laxson, San Jose, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Fairchild Imaging, Milpitas, CA

(21) Appl. No.: 10/197,967

(22) Filed: Jul. 16, 2002

(51) Int. Cl. H04N 5/335

(52) U.S. Cl. 348/218.1

(57) ABSTRACT

Large area cameras that sense light using charge coupled devices are provided. The large area cameras have a scintillator that senses short wavelength (e.g. x-rays) radiation and provides light at a longer wavelength. Optical fibers transmit the light to charge coupled devices arranged in an M×N array. Subsets of the image signals can be summed together to increase signal strength and frame rate. The image signals can be amplified and digitized to accomplish image reconstruction in near-real time for a plurality of CCDs. To accomplish image reconstruction in near-real time for a plurality of CCDs, the digitized signals for one image frame are stored in first memory circuits, while image signals from another frame are read out of second memory circuits. The image signal are written into and read out of the memory circuits in configurations that are independent of the orientation of the CCDs within the CCD array. The image reconstruction circuitry can simultaneously read and write signals into memory at different rates, typically reading faster than writing.

### CROSS-REFERENCES TO RELATED APPLICATIONS

This patent application is related to the following U.S. Patent Applications that are filed concurrently herewith and which are all incorporated by reference herein:

1. U.S. patent application Ser. No. ______ (Attorney Docket Number 013843-003600US) to Tinnerino et al., entitled Charge Coupled Devices in Tiled Arrays,

2. U.S. patent application Ser. No. ______ (Attorney Docket Number 013843-004200US) to Natale Tinnerino, entitled Image Reconstruction Techniques for Charge Coupled Devices,

3. U.S. patent application Ser. No. ______ (Attorney Docket Number 013843-003700US) to Jose Camara, entitled Charge Coupled Device Sensor With Variable Resolution, and

4. U.S. patent application Ser. No. ______ (Attorney Docket Number 013843-003200US) to Wen et al., entitled Large Area, Fast Frame Rate Charge Coupled Device.

### BACKGROUND OF THE INVENTION

The present invention relates to large area cameras that comprise charge coupled devices, and more particularly, to large area charge coupled device cameras that are highly sensitive and that have a high signal-to-noise ratio.

Charge coupled devices (CCDs) are light sensitive elements that are formed on a semiconductor wafer. CCDs contain a plurality of photodetecting picture elements (pixels). The pixels can detect light and output an electrical signal in response to the light. The magnitude of the output electrical signal is indicative of the intensity of the light that reaches the pixel.

CCDs can sense light from an object. The pixels in the CCD sense the light from the object and output electric signals indicative of the intensity of the impinging light rays. The output electrical signals can be stored and reconstructed to produce an image of the object. CCDs are very sensitive to light. Therefore, the image produced can be a very accurate reproduction of the object. CCDs can be used to build an imaging device or a camera.

CCDs are usually formed on a semiconductor wafer that is a few inches in width. The small size of a typical CCD limits the light sensing area of the imaging device. It would therefore be desirable to provide an imaging device that has a larger light sensing area than a typical single CCD. It would also be desirable to provide an imaging device that provides a fast enough frame rate to be used as a video camera.

### BRIEF SUMMARY OF THE INVENTION

The present invention provides cameras that sense electromagnetic radiation (e.g., light) using charge coupled devices. Cameras of the present invention can sense radiation such as x-rays using a scintillator device. Direct radiation such as x-rays will damage the charge coupled devices. Therefore, a scintillator is used to convert short wavelength x-rays into longer wavelength electromagnetic radiation that is transmitted to the charge coupled devices through arrays of optical fibers.

Because charge coupled devices are highly sensitive to light (and other wavelengths of electromagnetic radiation) and have very low noise, cameras of the present invention can create clear and sharp images from low doses of radiation. Cameras that sense low doses of radiation are especially important for surgeries that are performed in real-time over a relatively long period of time. It may be necessary to provide a fluoroscopic (i.e., continuous) x-ray image of a patient throughout surgery. Continuously exposing patients to high doses of x-rays over long periods of time during a long surgical procedure is highly undesirable. Cameras of the present invention can significantly reduce the radiation dosage that a patient is exposed to for a given amount of time during surgery also longer procedures are possible before maximum dosage limits are reached, because they are sensitive to much lower doses of x-rays.

The charge coupled devices are placed next to each other on a common plane to provide a larger light sensing area. Each of the charge coupled devices has a multitude of photo-sensing pixels. The pixels provide charge signals indicative of electromagnetic radiation impinging upon the charge coupled devices. Signals from the pixels can be summed together using a binning technique to increase the signal-to-noise ratio, signal strength and frame rate and variable resolution. The summed signals are then converted to digital signals and then stored in memory. The stored digital signals are then used to reconstruct images on a display screen. The cameras of the present invention can provide image data at a fast enough frame rate for video.

### BRIEF DESCRIPTION OF THE DRAWINGS

FIG. 1 illustrates a system diagram of an embodiment of a camera of the present invention;

FIG. 2 illustrates a cross sectional view of embodiment of a camera of the present invention;

FIG. 3 illustrates an exploded view of an embodiment of a camera of the present invention;

FIG. 4A illustrates signal processing circuitry for signals from the charge coupled devices (CCDs) according to the present invention;

FIG. 4B illustrates a CCD with eight channels in accordance with the present invention;

FIG. 5 illustrates memory storage devices for signals from the CCDs and associated circuitry in accordance with the present invention;

FIG. 6A illustrates an array of charge coupled devices (CCDs) in accordance with the present invention;

FIGS. 6B-6C illustrate graphs of the output signals of CCDs in accordance with the present invention;

FIG. 6D illustrates graphs that show the timing of signals that pass through cameras of the present invention;

FIG. 7 illustrates elements associated with a PCI bus that are used to display video frames in accordance with the present invention;

FIG. 8 illustrates an M×N array of charge coupled devices in accordance with the present invention;

FIG. 9 illustrates a charge coupled device, a horizontal shift register, a summing well, an amplifier, and associated circuitry in accordance with the present invention;

FIGS. 10-11 illustrates cross sections of first and second embodiments of seamless imaging devices in accordance with the present invention;

FIG. 12 illustrates another cross section of a seamless imaging device in accordance with the present invention;

FIG. 13 illustrates a beveled fiber optic array in accordance with the present invention;

FIGS. 14A-14B illustrate visualizations of the image results obtained from sensor pixels in accordance with embodiments of the present invention;

FIGS. 15A-15B illustrate configurations of tiled charge coupled devices in accordance with embodiments of the present invention;

FIG. 16 illustrates an array of charge coupled devices that are formed with an even reference plane in accordance with the principles of the present invention; and

FIG. 17 illustrates image reconstruction circuitry for a charge coupled device with four channels in accordance with the present invention.

### DETAILED DESCRIPTION OF THE INVENTION

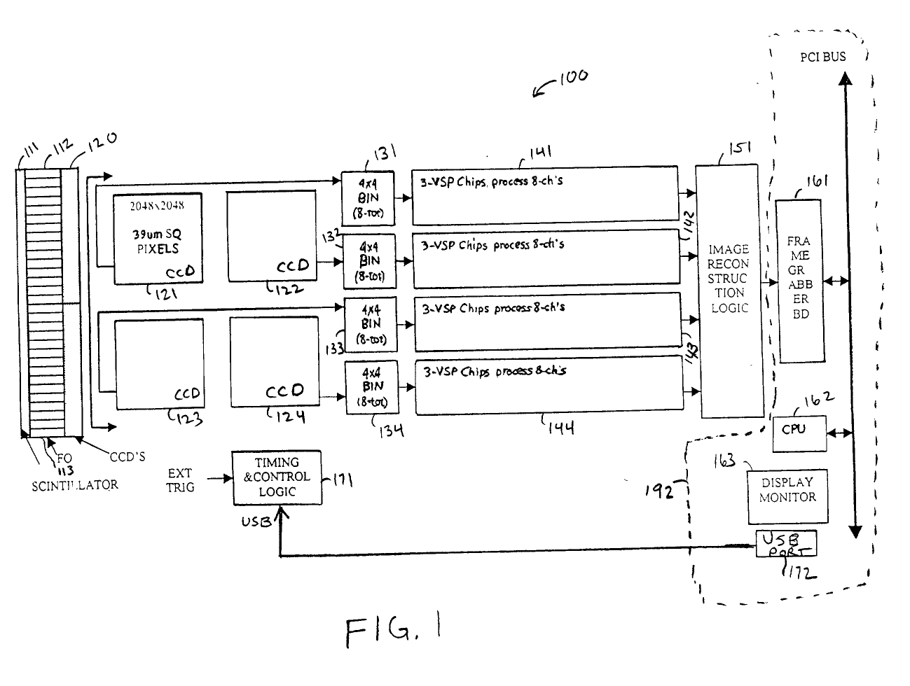

FIG. 1 illustrates a block diagram of an embodiment of a large area charge coupled device camera 100 of the present invention. Camera 100 includes a scintillator 111, four optical fiber arrays (two optical fiber arrays 112-113 are shown in FIG. 1), and an array 120 of charge coupled devices. Scintillator 111 may be, for example, a cesium iodide scintillator.

Elements 111, 112, and 120 are shown in cross section in FIG. 1. Array 120 includes four charge coupled devices (CCDs) 121-124 arranged in a 2×2 array. Using an array of four CCDs provides a large light sensing area for camera 100.

In other embodiments of the present invention, array 120 can include any number of charge coupled devices and fiber optic assemblies arranged in an M×N array to increase the light sensing area of the camera (e.g., 2×1, 2×3, 2×4, 3×3, 4×4, etc.). Each of the CCDs has an array of optical fibers.

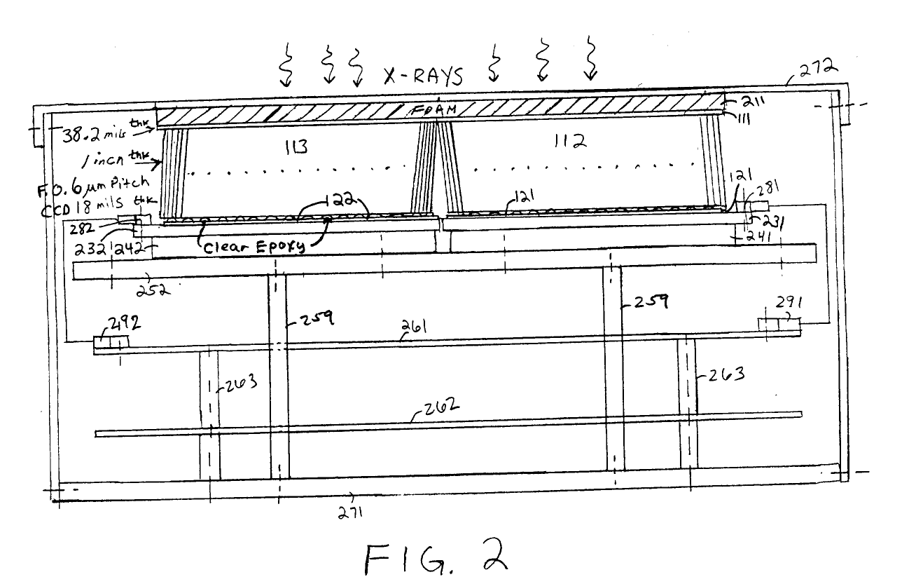

FIG. 2 illustrates a more detailed cross sectional diagram of portions of camera 100 of the present invention. A foam layer 211 may be placed on top of scintillator 111 as shown in FIG. 2. Foam 211 holds scintillator 111 against fiber optic assembly 112 via pressure applied through cover 272 and to protect scintillator 111 from damage. Scintillator 111 may, for example, be 38.2 mils thick. The CCD array may, for example, be 18 mils thick and 8×8 cm².

Optical fiber arrays are located between scintillator 111 and array 120. A separate fiber optic array is connected between scintillator 111 and each CCD in array 120. Thus, camera 100 has four fiber optic arrays, one for each of the four CCDs 121-124 in array 120. The fiber optic arrays may be, for example, 1 inch thick, and the individual optical fibers may be, for example, at 6 μms pitch. Only fiber optic arrays 112-113 are shown in the cross sectional views of FIGS. 1-2 for simplicity.

Fiber optic array 112 is connected between scintillator 111 and CCD 121, and fiber optic array 113 is connected between scintillator 111 and CCD 122, as shown in FIG. 2. The optical fiber arrays are attached to the CCDs by clear epoxy as shown in FIG. 2.

Each fiber optic array includes numerous optical fibers that extend from the scintillator 111 to the upper surface of array 120 of charge coupled devices. The optical fibers in the optical fiber arrays are epoxied to the CCD and slant inward toward adjacent CCDs as shown in FIG. 2 to reduce the light gap that appears between the CCDs in the output image. This feature of the fiber optic arrays is discussed in further detail in commonly-assigned U.S. patent application Ser. No. ______ (Attorney Docket Number 013843-003600US) mentioned above.

Radiation (e.g., x-rays, etc.) from a radiation source passes through an object (such as a patient's body) and reaches scintillator 111 through foam layer 211 as shown in FIG. 2. The x-rays that pass through denser portions of the object are more attenuated. Therefore, the x-rays that reach scintillator 111 contain an image of the object.

When the x-rays from the object impinge upon the upper surface of scintillator 111, scintillator 111 converts the x-rays into electromagnetic radiation that has a longer wavelength. For example, scintillator 111 may shift the wavelength of x-rays into the visible spectrum, the ultra-violet spectrum, or the infrared spectrum. The electromagnetic radiation output by scintillator 111 is referred to herein as light (even though it need not be visible light).

Electromagnetic radiation from scintillator 111 optically enters the four fiber optic arrays. Optical fibers in the optical fiber arrays conduct electromagnetic radiation (e.g., light) and further protect the CCDs from damaging x-rays. The electromagnetic radiation travels through optical fibers in the arrays to charge coupled devices 121-124. Charge coupled devices (CCDs) 121-124 are shown face up in FIG. 1.

Optical fibers in the fiber optic arrays contact pixels in charge coupled devices (CCDs) 121-124 through the clear epoxy attachment. Electromagnetic radiation from the scintillator travels through the optical fibers to pixels in the CCDs. Pixels in the charge coupled devices are sensitive to particular wavelengths of electromagnetic radiation (e.g., ultraviolet, visible light, and infrared light).

The electromagnetic radiation at these wavelengths is sensed by the pixels in the CCDs. The pixels provide signals in response to the electromagnetic radiation received through optical fibers. Signals from the pixels are temporarily stored in vertical shift registers that are formed in a semiconductor wafer.

In one embodiment of the present invention, the charge coupled devices may comprise interline transfer charge coupled devices. Interline transfer CCDs have columns of vertical shift registers in between each of the columns of pixels (i.e., photosites). By forming a vertical shift register next to each photosite, the signals generated in the photosites only have to travel a short distance to be stored in the vertical shift registers. Interline transfer CCDs are useful in video camera applications, because they can provide a fast data transfer rate. A fast data transfer rate is needed to produce continuos frames of video images on a display screen.

Camera 100 can create images from low doses of radiation, because the CCD sensors are very sensitive to light. Cameras that sense low doses of radiation are especially important for surgeries that are performed over a long period of time. For example, it may be desirable to provide a continuous x-ray image of the patient throughout the surgery. Exposing patients to high doses of x-rays over long periods of time during a long surgery procedure is highly undesirable. Because camera 100 is sensitive to lower doses of radiation, the present invention can significantly reduce the amount of radiation that a patient is exposed to during surgery. Conversely longer operations (that may not have been previously considered because they took too long) may be performed at maximum allowable dosage levels.

Each of CCDs 121-124 are placed in a carrier device (e.g., a ceramic header) that provides support to the CCD. For example, CCD 121 is supported by carrier 231, and CCD 122 is supported by carrier 232 as shown in FIG. 2. Each of the carriers is attached (e.g. epoxied) to a corresponding saddle. For example, carrier 231 is attached to saddle 241, and carrier 232 is attached to saddle 242.

The saddles are screwed onto a common base unit 252. Further details of techniques for forming a camera with tiled arrays of charge coupled devices are discussed in commonly-assigned U.S. patent application Ser. No. ______ (Attorney Docket Number 013843-003600US) mentioned above.

The carriers each include a set of output pins. For example, carrier 231 includes output pins 281, and carrier 232 includes output pins 282. The carriers may include printed circuits or wires that carry signals from the CCD to the output pins. The output pins of the carriers are connected to input pins on printed circuit board 261 through conducting wires. For example, output pins 281 of carrier 232 are connected to input pins 292, and output pins 281 of carrier 231 are connected to input pins 291. Printed circuit board 261 may contain circuit elements such as VSP chips 141 and image reconstruction logic 151. These circuits are discussed further below. Printed circuit board 261 is attached to a lower portion 262 through supports 263.

The elements of camera 100 are placed on top of each other and sealed inside a housing container. The housing container includes an upper portion 272 and a lower portion 271. Base unit 252 may be supported on lower housing container 271 by legs 259 through holes in PCB 261 and lower portion 262.

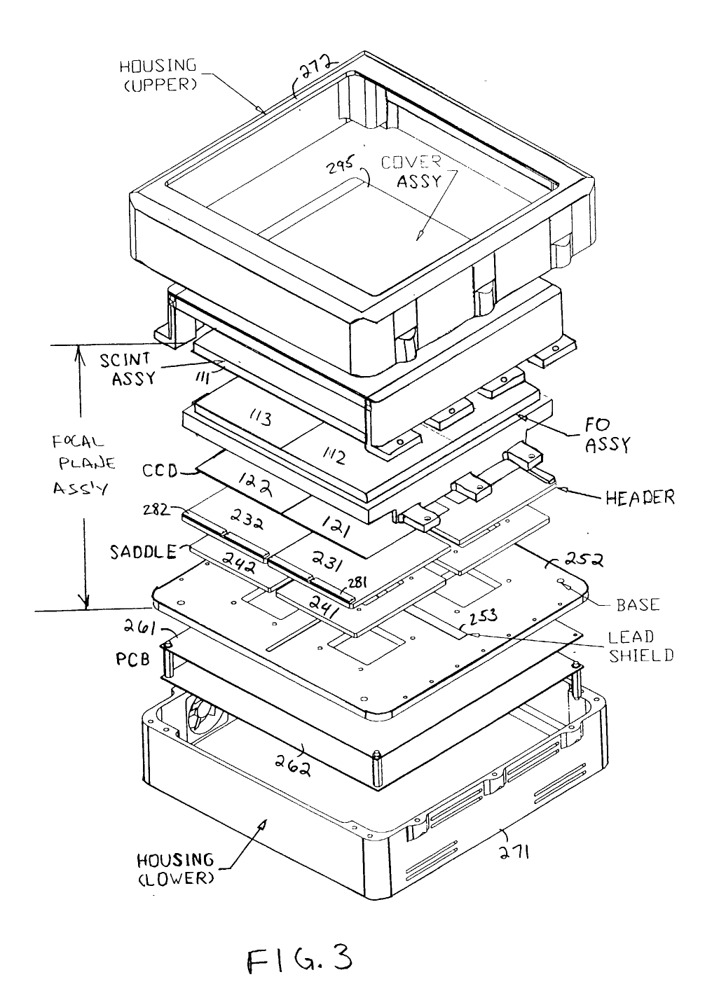

FIG. 3 illustrates an exploded view of camera 100. The various layers of camera 100 are shown in FIG. 3. Scintillator 111 is covered by cover assembly 295, which includes foam 211. Base 252 may include lead shield 253 that is placed on base 252 between the saddles to provide x-ray shielding. Other areas of camera 100 are also lead shielded.

Referring again to FIG. 1, signals from the pixels in CCDs 121-124 are transferred into horizontal shift registers. Signals from more than one pixel in the same area of a CCD sensor can be summed together to increase the signal-to-noise ratio, and to increase the data transfer rate (at the expense of lower resolution). This technique is called binning. Signals from a selected number (P) of rows are summed in vertical summing wells or in the horizontal shift registers. Signals from a selected number (Q) columns are summed in horizontal summing wells. Each CCD sensor 121-124 has dedicated binning circuitry 131-134 (including registers and summing wells) that store and sum the signals from the pixels in that CCD.

Signals from the rows of pixels can be summed together first, and then signals from the columns of pixels are summed together. In another embodiment, signals from the columns of pixels are summed together first, and then signals from the rows of pixels are summed together. In an further embodiment, binning is not applied to the pixels signals (i.e., 1×1 resolution).

Any number of signals from the pixels may be summed together in the binning circuitry. For example, four signals from 16 adjacent pixels in 4 adjacent rows and 4 adjacent columns can be summed together (i.e., 4×4 binning). Further details of binning techniques are discussed in commonly-assigned U.S. patent applications Ser. Nos. ______ and ______ (Attorney Docket Numbers 013843-003600US and 013843-004200US).

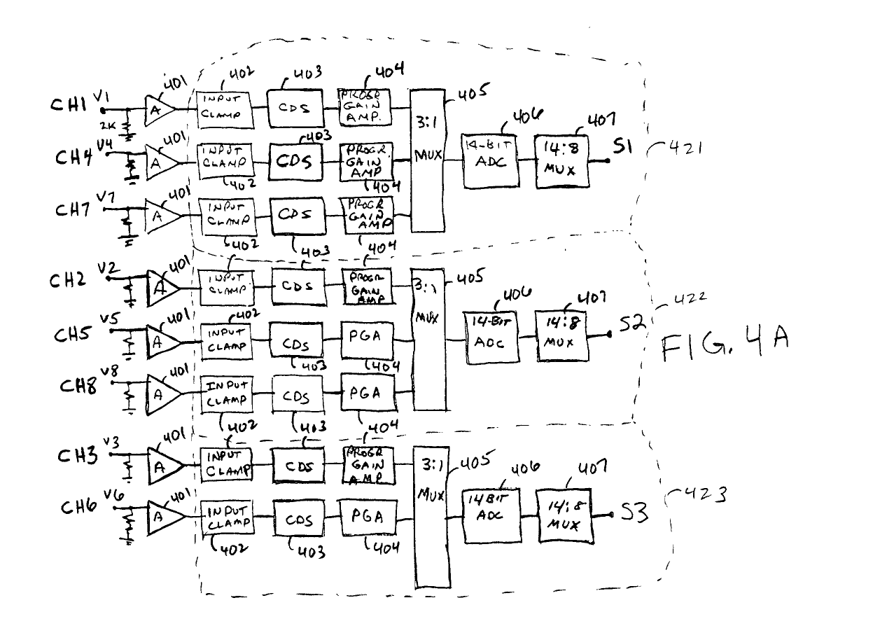

Pixels in each CCD 121-124 may be grouped together in any number of channels. For example, the CCDs 121-124 may each contain 2048 rows and 2048 columns of pixels. Each of CCDs 121-124 may be divided into eight channels as shown in FIG. 4A. Each channel then comprises 256 columns of pixels.

Signals from each channel in each CCD sensor are transferred and summed together in separate circuit elements. Dividing the pixels in each CCD into channels significantly reduces the amount of pixel signals that each set of circuit elements has to process. By routing the signals from the pixels into additional registers and summing wells, the speed of the camera can be significantly increased.

Circuits 131-134 represent the on chip binning technique and each store and sum signals from multiple channels in a single CCD sensor. Circuits 131-134 output binned signals to signal processor VSP chips. Signals from each CCD are provided to three VSP chips. Each box 141-144 in FIG. 1 includes three VSP chips. The VSP chips are discussed in more detail below.

The output signals of each VSP chip are transferred to image reconstruction logic 151. Image reconstruction logic 151 stores the image data for each video frame in memory circuits. Image reconstruction logic 151 is also discussed in more detail below. The image is then transferred to frame grabber 161. Frame grabber 161 then transfers video image data to a PCI bus that is controlled by CPU 162. The image data is used to display video images on video display monitor 163. The elements of FIG. 1 that are not in region 192 may be placed on the same circuit board.

Many types of signal processing chips that are designed to process signals from CCDs can be used with cameras of the present invention. Examples of VSP chips that can be used with the present invention are shown in FIG. 4A.

FIG. 4A illustrates a more detailed diagram of one of boxes 141-144. Three VSP chips 421-423 are shown in FIG. 4A. Each box 141-144 has three VSP chips 421-423 as shown in FIG. 4A.

Signals from circuits 131-134 are amplified by pre-amplifiers 401. Each set of VSP chips 421-423 receives signals from all of the channels on one of the CCDs in the CCD array.

In the example of FIG. 4A, VSP chips 421-423 receive signals from a CCD that has 8 channels. An example of a CCD 499 with eight channels and 2048×2048 pixels is shown in FIG. 4B. The first inputs of VSP chips 421-423 are coupled to receive signals from channel 1, channel 2, and channel 3, respectively, as shown in FIG. 4A. The second inputs of VSP chips 421-423 are coupled to receive signals from channel 4, channel 5, and channel 6, respectively. The third inputs of VSP chips 421-422 are coupled to receive signals from channel 7 and channel 8, respectively.

FIG. 4A has eight pre-amplifiers 401, one for each channel in the corresponding CCD sensor. Each VSP chip 421-423 includes at least one input clamp 402, one correlated double sampler 403, and one programmable gain amplifier 404 for each channel.

Each VSP chip 421-423 also has a 3:1 multiplexer 405, a 14-bit analog-to-digital converter 406, and a 14:8 multiplexer 407. These circuit elements are coupled together as shown in FIG. 4A. An example of a VSP chip that may be used with cameras of the present invention is an AD9814 manufactured by Analog Devices Inc., of Norwood Mass. Further details of the operation of the AD9814 are discussed in AD9814 1999 Datasheet entitled “Complete 14-Bit CCD/CIS Signal Processor,” Rev. 0, pages 1-15, which is incorporated herein by reference.

Each VSP chip 421-423 samples the input waveforms using CDS 403. The sampled signals from each channel are amplified using programmable gain amplifiers 404. Multiplexers 405 multiplex the signals from two or three channels onto one signal line. The signals are then converted to 14 bit digital signals by A-to-D converters 406. Multiplexers 407 multiplexes the 14 bit signals into 8 bit output words. Each multiplexer 407 provides signals from two or three CCD channels to output terminals S1, S2, or S3 as shown in FIG. 4A.

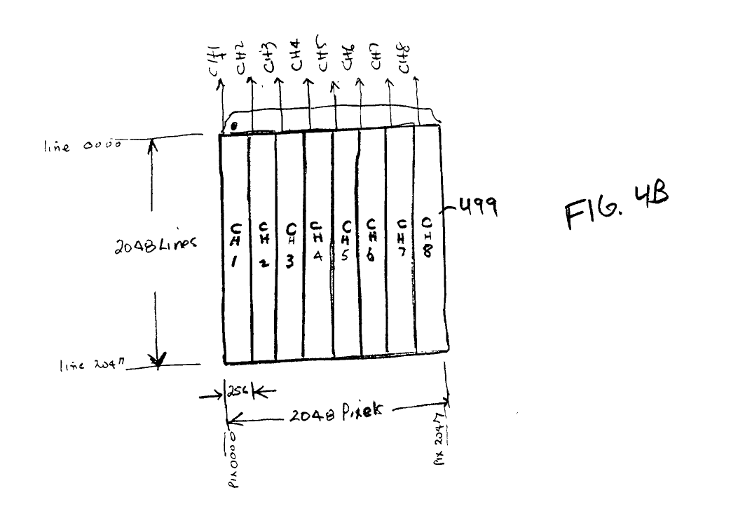

Referring again to FIG. 1, the output signals of boxes 141-144 are provided to image reconstruction logic 151. Image reconstruction logic 151 include four identical sets of RAM memory circuits and associated circuit elements. Each of the four sets of memory circuits in reconstruction logic 151 includes 2 RAM memory circuits that store signals from only one of the CCDs 121-124. Two RAM memory circuits and associated circuit elements that store signals from one CCD (2K×2K with 8 channels and 1×1 binning) are illustrated in FIG. 5.

Referring now to FIG. 5, output terminals S1, S2, and S3 (from FIG. 4A) are coupled to inputs of 8 bit registers 511-516. Registers 511-516 stores the 8 bit words from the VSP chips. Clock signal CLK controls the shifting of signals into and out of registers 511-516. When CLK is HIGH, a first set of 8 bit words at terminals S1-S3 are stored in registers 511, 513, and 515. When CLK is LOW, a second set of 8 bit words at terminals S1-S3 are stored in registers 512, 514, and 516.

The signals stored in registers 511-516 are then transferred into 16 bit register 522. Multiplexer 521 alternately couples registers 511-516 to registers 522. During a first period of time, 16 bits from registers 511 and 512 are shifted into 16 bit register 522. During a second period of time, 16 bits from registers 513 and 514 are shifted into 16 bit register 522. During a third period of time, 16 bits from registers 515 and 516 are shifted into 16 bit register 522. Decoder 551 controls the timing of when signals from registers 511-516 are shifted into register 522.

After a set of 16 bit signals are stored in register 522, the signals are shifted out of register 522 and written into RAM memory circuit 535 or RAM memory circuit 536. Another clock signal SUB PC′ controls the shifting of signals through shift register 522 and into memory circuits 535-536. Switches 541-542 control whether signals from register 522 are stored in memory circuit 535 or memory circuit 536. Memory circuits 535 and 536 may have any appropriate number of memory cells (e.g., 4M×16 RAM).

Write address generation circuit 531 outputs 24 address signals that determine the order in which the 16 bit signals are stored in and subsequently read out of memory circuits 535 and 536. Read address generation circuit 532 outputs 24 bit address signals that select the memory locations where the 16 bit signals from register 522 are read from memory circuits 535 and 536.

Write address generation circuit 531 accepts four input signals FrSt (frame start), VST (vertical start), HST (horizontal start), and MCLK′. Signals MCLK′, HST, VST, and FrSt may be generated by timing and control logic circuit 171 (FIG. 1). Clock signals MCLK′, PC, and SUB PC′ are shown graphically in FIG. 5. Circuit 552 generates clock signal SUB PC′ in response to clock signal MCLK′. Clock signal SUB PC′ has a period that is three times as long as the period of clock signal MCLK′. Circuit 553 generates clock signal PC in response to clock signal SUB PC′. Clock signal PC has a period that is eight times as long as the period of clock signal SUB PC′.

Further details of write address generation circuit 531 are shown at the bottom of FIG. 5. Active pixel counter 554 generates 12 bit write generation address signals. The 12 bit address output signals of active pixel counter 554 are used to select each of the 2048 columns of memory cells in memory circuits 535 and 536.

Active line counter circuit 555 also generates 12 bit write address generation signals. The 12 bit address output signals of active line counter 555 are used to select each of the 2048 rows of memory cells in memory circuits 535 and 536. Active pixel counter 554 and active line counter 555 generate the write address generation signals in response to signals HST, VST, SUB PC′, and FrSt as shown in FIG. 5. Active pixel counters 557 and active line counter 558 generate the read address generation signals in response to signals SUB PC″, Fst′, HST′, and VST′.

Read address generation circuit 532 accepts four input signals FrSt′ (frame start), VST′ (vertical start), HST′ (horizontal start), and MCLK. Signals MCLK, HST′, VST′, and FrSt′ may be generated by timing and control logic circuit 171 (FIG. 1).

Further details of read address generation circuit 532 are shown at the bottom of FIG. 5. Active pixel counter 557 generates 12 bit read address generation signals. The 12 bit address output signals of active pixel counter 557 are used to select each of the 2048 columns of memory cells in memory circuits 535 and 536.

Active line counter circuit 558 also generates 12 bit read address generation signals. The 12 bit address output signals of active line counter 558 are used to select each of the 2048 rows of memory cells in memory circuits 535 and 536. Active pixel counter 557 and active line counter 558 generate the read address signals in response to signals HST′, VST′, SUB PC″, and FrSt′ as shown in FIG. 5. Note in this example the read address generator reads four times faster than the write address generator writes.

The circuitry of FIG. 5 can be used to provide a fast frame rate in a tiled CCD array. A first set of pixel signals from a CCD are stored into memory circuit 535 during a first period of time. The first set of signals may represent a first frame of a video image. Subsequently, a second set of pixels signals from the CCD representing a second frame are written into memory circuit 536, while the first set of signals is simultaneously read out of memory circuit 535. The first set of signals is then used to produce a frame of an image on a display screen.

A third set of pixel signals from the CCD representing a third frame are written into memory circuit 535, while the second set of signals is simultaneously read out of memory circuit 536. This process repeats so that pixel signals from one frame are stored, while signals from a previous frame are read out of memory and used to display an image frame. The time delay between a frame exposure and outputting the reconstructed video for that frame is minimized using this technique.

The time delay to write pixel signals into memory circuits 535 and 536 is based on the delay for one CCD, because the pixel signals are written into memory along separate circuit paths using separate circuit elements. However, the time delay to read pixel signals out of memory circuits 535 and 536 and to create an image frame is based on for all four CCDs, because the output data of reconstruction logic 151 is merged into a single data stream (FIG. 1). Therefore, camera 100 reads digitized binned pixel signals out of memory circuits 535 and 536 four times as fast as it writes the digitized binned pixel signals into memory circuits 535/536. Further details of techniques that provide a fast frame rate in a camera with charge coupled devices is discussed in U.S. patent application Ser. No. ______ (Attorney Docket Number 013843-004200US) mentioned above.

Signal W/R controls when signals from register 522 are stored in memory circuit 535 and when signals from register 522 are stored in memory circuit 536. FrSt resets flip-flop 556. Flip-flop 556 provides read/write signal (W/R) at its Q output. Signal W/R is provided to the select inputs of multiplexers 533 and 534 as well as the read/write inputs of memory circuits 535 and 536.

The W/R signal determines if multiplexers 533 and 534 couple write address generation circuit 531 to memory circuit 535 or to memory circuit 536. When signal W/R is HIGH, multiplexer 533 provides the 24 bit address signals from write address generation circuit 531 to the address input of memory circuit 535. Memory circuit 535 is in write mode when W/R is HIGH, and switch 541 couples register 522 to the D input of memory 535. Pixel signals from all eight channels in a CCD are transferred out of register 522 and stored in memory circuit 535. Pixel signals from an entire video frame are written in memory 535 in one half cycle of W/R.

When the W/R signal is LOW, multiplexer 534 provides the 24 bit address signals from write address circuit 531 to the address input of memory circuit 536. Memory circuit 536 is in write mode when W/R is LOW, and switch 542 couples register 522 to the D input of memory 536. Pixel signals from all eight channels in a CCD are transferred out of register 522 and stored in memory circuit 536. Pixel signals from a second video frame are stored in memory 536 in one half cycle of W/R.

When W/R is LOW, multiplexer 534 couples read address generation circuit 532 to memory 535. Switch 541 couples the D output of memory 535 to the input of register 543. Read address generation circuit 532 provides read address signals to memory 535. The read address signals select the order in which the pixel signals are read out of memory cells in memory circuit 535. The pixel signals indicative of the first frame are read out of memory 535 and transferred into register 543, while signals indicative of the second frame are shifted out of register 522 and written into memory 536.

When W/R is HIGH, multiplexer 533 couples read address generation circuit 532 to memory 536. Read address generation circuit 532 provides read address signals to memory 536. The read address signals select the order in which the pixel signals are read out of memory cells in memory circuit 536. Switch 542 couples the D output of memory 536 to the input of register 543. The pixel signals stored in memory 536 are then read out of memory 536 and transferred to register 543, while signals indicative of a third video frame are stored in memory 535.

Thus, pixel signals from one frame are written into memory 536 while pixel signals from a previous frame are simultaneously read out of memory 535. Also, pixel signals from one frame are written into memory 535 while pixel signals from a previous frame are simultaneously read out of memory 536. This technique provides a higher frame rate for the reconstructed output video image. A faster frame rate is important for CCD imaging devices of the present invention that are used as video cameras.

The time delay for each frame is only the time it takes to download signals from one CCD into memory 535 or memory 536, because the signals from each CCD are downloaded in parallel using separate circuits. Each CCD in the array stores its pixel signals in a separate set of memory circuits 535 and 536. Signals from all four CCD sensors can be read out of four corresponding memory circuits and used to form a video frame in a very short time.

Each address signal from circuit 531 selects the row and the column where each pixel signal is written into memory circuits 535 and 536. The address signals from circuit 531 cause the pixels signals from the CCD to be stored in a configuration within memory circuits 535 and 536 that is not dependent on the direction that the pixel signals are read out of the CCD.

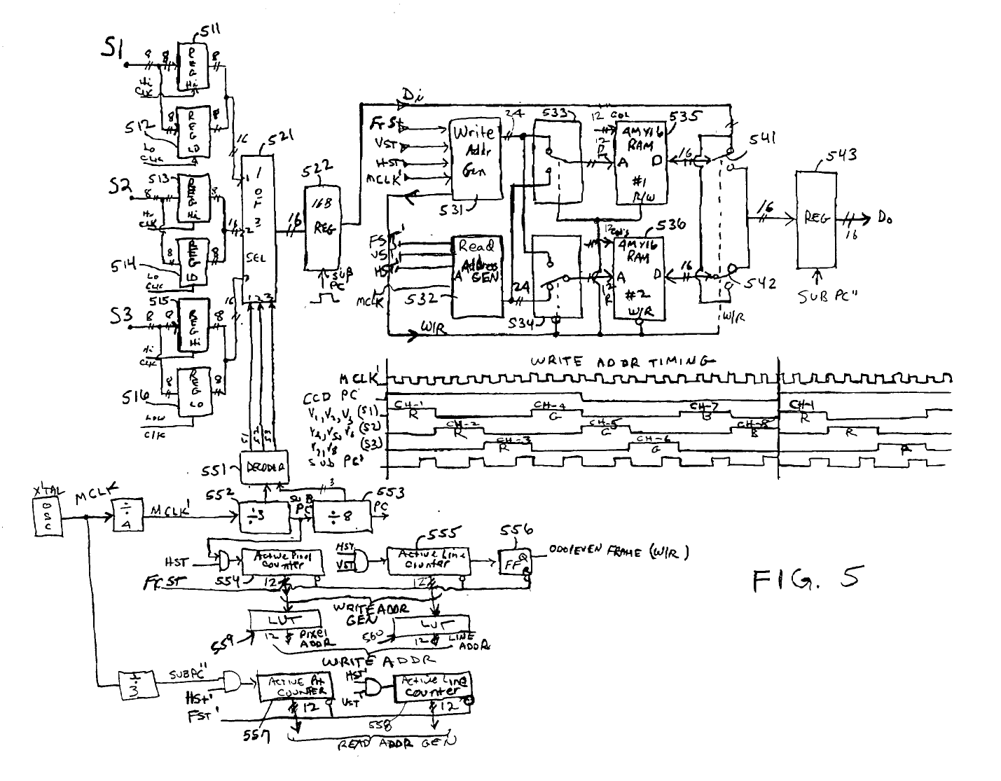

FIG. 6A illustrates the problem. Four CCD sensors 121-124 are shown in FIG. 6A. Each CCD sensor 121-124 has a set of horizontal shift registers 121A-124A, respectively. Signals generated by pixels in the CCD sensors are transferred into the horizontal shift registers using vertical shift registers (not shown) within each CCD. The pixel signals can be summed together internally using a binning technique. For example, 16 pixel signals in 4 adjacent rows and four adjacent columns may be summed together in a 4×4 binning technique. If CCDs 121-124 each have 2048 rows and 2048 columns of pixels, then the 4×4 binned pixel signals output by the summing wells comprise 512 rows and 512 columns of signals per CCD sensor.

In the example of FIG. 6A, pixel signals for one frame may be read out of CCD 121 row by row from the top edge to the bottom edge of CCD 121 using registers 121A. The binned pixel signals are output by the summing well starting from line 1 (i.e., row 1) and continuing through line 512 (i.e., row 512). At the same time, pixel signal from the same frame may be read out of CCD 123 row by row from the bottom edge to the top edge of CCD 123 using registers 123A. The binned pixel signals are output by the summing well starting from line 1 and continuing through line 512.

If the circuitry and signals shown in FIGS. 4A and 5 are the same for all four CCDs in the array, then the order that the pixels signals are stored in corresponding sets of memory circuits 535 and 536 is dependent upon how the pixel signals are read out of the CCD. The pixel signals from CCD 121 that are stored in the first row of memory cells are from the top row (line 1) of pixels in CCD 121. The pixel signals from CCD 123 that are stored in the first row of memory cells are from the bottom row (line 1) of pixels in CCD 123. The pixel signals are treated the same for all four CCDs when they are read out of memory and used to reconstruct a frame of the image. Therefore, the portion of the frame sensed by CCD 123 will be rotated 180 degrees with respect to the portion of the frame sensed by CCD 121.

The same problem occurs with respect to the way the columns of pixel signals are read out differently from each CCD sensor. For example, columns of the pixel signals are read out of CCDs 121-122 from right to left, while the columns of pixel signals are read out of CCD 123-124 from left to right. If the pixel signals are stored in memory and processed the same way for each CCD sensor 121-124, then the portions of the video frames from each CCD sensor have a different orientation. For example, the portion of the video frame from CCD 122, is rotated 180 degrees with respect to the portion of the video frame from CCD 124.

To correct this problem, the pixel signals can be written into memory 535 and 536 in a configuration that is independent of the direction that the pixel signals are read out of the CCD. For example, signals from the bottom row of signals in each CCD sensor are stored in row 1 of the memory cells (in circuits 535 and 536). Signals from subsequent rows of pixels (from the bottom to the top of each CCD) are stored in consecutive rows of the memory cells. Signals from the leftmost column of pixels in each CCD sensor are stored in column 1 of the memory cells (in circuits 535 and 536). Signals from subsequent columns of pixels (from the left to the right of each CCD) are stored in consecutive columns of the memory cells. Thus, the pixel signals are stored in the memory cells in a configuration that is independent of the orientation of each CCD sensor within the CCD array.

Alternatively, pixel signals can be written into memory cells in circuits 535 and 536 in any pattern or configuration. The pixel signals are then read out of circuits 535 and 536 using read address bits in a configuration that is independent of the direction that the pixels signals were read out of the CCDs. In this embodiment, the write address signals (but not the read address signals) dictate patterns that re-orient the order of the pixel signals so that they are independent of the readout direction of each CCD.

The timing diagrams FIGS. 6B-6C illustrates how the order of the pixels signals has changed when the pixels signals are read out circuits 535 and 536. CCD 121 is in quadrant I (QI) of the array, CCD 122 is in quadrant II (QII) of the array, CCD 123 is in quadrant III (QIII) of the array, and CCD 124 is in quadrant IV (QIV) of the array.

FIG. 6B illustrates signals from CCDs 121-122 after they are read out of memory circuits 535 and 536. As shown in FIG. 6B, the binned pixel signals are read out of memory circuits 535 and 536 starting with horizontal line 1 of CCDs 121-122 and continuing sequentially to horizontal line 512 of CCDs 121-122. Line 1 from CCD 121 is read out first, then line 1 from CCD 122, then line 2 from CCD 121, then line 2 from CCD 122, then line 3 from CCD 121, etc. Signals from the 64 binned rows in each channel are read out first from channel 1, then channel 2, then channel 3, then channel 4, then channel 5, then channel 6, then channel 7, and then channel 8 in CCDs 121-122.

FIG. 6C illustrates the order that signals from CCDs 123-124 are read out of memory circuits 535-536. Binned pixel signals are read out of memory circuits 535 and 536 starting with horizontal line 512 of CCDs 123-124 and continuing sequentially to horizontal line 1 of CCDs 123-124. Line 512 from CCD 123 is read out first, then line 512 from CCD 124, then line 511 from CCD 123, then line 511 from CCD 124, then line 510 from CCD 123, etc. Signals from the 64 binned rows in each channel are read out first from channel 8, then channel 7, then channel 6, then channel 5, then channel 4, then channel 3, then channel 2, and then channel 1 in CCDs 123-124.

All of the signals sensed by CCDs 121-122 in one frame are read out of memory circuits 535-536 first. Subsequently, all of the signals sensed by CCDs 123-124 in that frame are read out of memory circuits 535-536. Thus, the output data stream of image reconstruction circuitry 151 for a particular video frame starts with signals from CCDs 121 and 122 (e.g., as shown in FIG. 6B), and ends with signals from CCDs 123 and 124 (e.g., as shown in FIG. 6C).

The output signals from the four registers 543 that are associated with each of the four CCDs can be controlled by a multiplexer. The multiplexer has four inputs coupled to each register 543 and one output. The multiplexer combines the data signals from CCDs 121-124 into the sequence discussed above and shown in FIGS. 6B-6C.

Thus, the signals read out the four sets of memory circuits 535/536 are ordered in a configuration that is independent of how the pixels signals are actually read out of each CCD. The output signals of the four sets of memory circuits 535/536 begin with the top rows in CCDs 121-122 and continue down to the bottom rows of CCDs 121-122. Then, signals from CCDs 123-124 are added to the data stream starting from the top rows and ending with the bottom rows of CCDs 123-124. Within each row, the signals begin with the left column and continue to the right columns. This pattern is preserved for all of the CCD sensors regardless of the order that the pixel signals are read out of each sensor. This technique is also independent of the physical orientation of each CCD within the CCD array.

Data stored in lookup tables 559-560 determines the row and the column memory address signals that are output by write address generation circuit 531. These row and column address signals select a write configuration for memory circuits 535 and 536. The data in lookup tables 559-560 ensures that the pixel signals from each CCD are written into memory circuits 535 and 536 in a configuration that is independent of the direction that the pixels signals are read out of that CCD (and independent of the physical orientation of each CCD within the CCD array).

Read address generation circuit 532 outputs row and the column memory address signals that determine a read configuration for data in memory circuits 535 and 536. The pixel signals from each CCD are also read out of memory circuits 535 and 536 in a configuration that continues to be independent of the direction that the pixels signals are read out of that CCD (and independent of the physical orientation of each CCD within the CCD array). The rest of the signals and circuitry shown in FIG. 5 may be the same for each CCD sensor.

The write address bits output by circuit 531 are generated such that the 16 signal bits from register 522 are written into RAM 535 or 536 at the desired reconstruction addresses during each write cycle. This may be accomplished via a logic array look-up tables (e.g., lookup tables 559 and 560) within the write address generator 531 which outputs the desired reconstruction addresses to RAM 535 or 536 for each write cycle.

During the subsequent read cycle, the read address bits from circuit 532 cause the signal bits to be read out directly from RAM 535 or 536 in the desired order. This technique ensures that the pixel signals are also read out of the memory in a configuration that is independent of the orientation of each CCD in the CCD array and the direction that the pixel signals were read out of each CCD.

Alternatively this technique can be used to reconstruct during the read cycle instead of the write cycle. However, the preferred embodiment for this invention is to reconstruct during the write cycle because RAM's can usually be read out faster than they can be written into, and we are required to read out at least four times faster than we write if four tiled CCDs are used to achieve the same data transfer rate for the output signals.

If the physical orientation of one or more of the CCDs in the CCD array is changed, the image reconstruction techniques of the present invention can compensate for this change. For example, CCD 121 can be rotated 90 degrees with respect to its orientation in FIG. 6A. The write address signals from write address circuit 531 or the read address signals from read address circuit 532 can be reprogrammed to cancel out the change in the orientation of CCD 121. The write address signals can be changed by reprogramming the address data in lookup tables 559 and 560. Alternatively, the read address signals can be reprogrammed.

The write and read address signals can be reprogrammed to store and read the pixel signals in a configuration that is independent of the orientation of CCD 121 with respect to CCDs 122-124. If re-synchronization and re-clocking of the counters is required, timing and control generator circuitry can also be reprogrammed for signals HST, VST, HST′, and VST′. These signals may be programmed using the USB bus, for example.

FIG. 5 also illustrates a timing diagram for signals V1, V2, V3, V4, V5, V6, V7, and V8. Signals V1-V8 are the output signals from the eight channels of a CCD. The timing diagram shows the order of the eight signals output by the three VSP chips.

FIG. 6D illustrates the interrelationships between signals used by cameras of the present invention. X-rays may be passed through a patient's body in a series of ON-OFF pulses as shown in FIG. 6B. The period of the pulse may be, for example, 33.33 milliseconds (ms), and the ON period of the cycle may be, for example, 1-13 ms. Pixel signals are formed in the CCD sensors for each pixel during the ON period of the cycle when the x-rays impinge upon scintillator 111.

A downward pulse in the interline XFR signal indicates the period of time that the pixel signals are transferred from the photosites into the vertical shift registers. The pixel signals are shifted out the vertical shift registers when the CCD Readout signal is HIGH. The pixel signals are stored and summed together according to a particular binning arrangement as discussed above during the CCD Readout period. Subsequently, the pixel signals for each CCD sensor are sampled, amplified, converted to digital signals, and stored in registers as during “Rd CCD Image” period #1 shown in FIG. 6D.

As the pixel signals are digitized, the pixels signals for the first frame exposure are written into memory circuits 535 as discussed in detail above during “Write R-Memory” period #1. Subsequently, the pixel signals from the first frame are read out of memory circuit 535 and used to display the first frame on a video display screen during “Read R-Memory” period #1. At the same time, pixel signals from a second frame exposure are read out of the CCD sensors, processed, and written into memory circuit 536 during “Write R-Memory” period #2. Pixels signals from the second frame are read out of memory circuit 536 during “Read R-Memory” period #2, while pixel signals from a third frame exposure are written into memory circuit 535. The periods of pixel signals are also shown in FIG. 6B for 4×4 binning.

Referring again to FIG. 5, clock signal SUB PC″ synchronizes the shifting of signals through shift registers 543 from memory circuits 535 and 536 into frame grabber 161 (see FIG. 1). Digitized video data can be provided to frame grabber 161 at high data transfer rate (e.g., 40 MHz pixel rate). Frame grabber 161 acquires, pre-processes, and transfers images from the CCD sensors in real-time (or in near real-time) to the PCI bus at a high speed data rate (e.g., 200 Mbytes/sec.). Frame grabber 161 can transfer data formats of 8, 16, 24, or 32 bits per pixel. Frame grabber 161 may have a processor as its PCI bus interface. Frame grabber 161 may be able to buffer part of the image during busy cycles on the PCI bus, ensuring that no image data is ever lost.

One example of frame grabber 161 is the Viper-Digital frame grabber by Coreco Imaging of Montreal, Canada. Further details of the operation of the Viper-Digital frame grabber are discussed in the datasheet entitled “High Performance PCI Frame Grabber for Multitap Digital Camera,” dated 2002, which is incorporate herein by reference. Alternatively, other types of frame grabbers can be used for frame grabber 161.

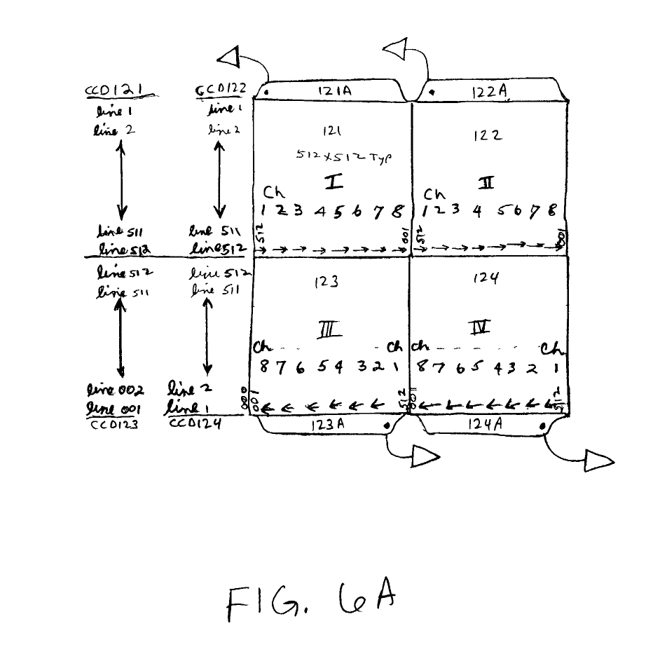

FIG. 7 illustrates an example of an output system for camera of the present invention. Frame grabber 161 accepts video data in 16 bit words and outputs data as 32 bit words onto the PCI bus line. Central processing unit (CPU) 162 controls the transfer of data bits on the PCI bus line. Video data bits from frame grabber 161 may be stored in RAM circuitry 602 or in hard drives 611-612 through SCSI Adapter 605.

Graphic adapter cards 621-622 read video data from the PCI bus and provide the video data to computer monitor 625 and medical monitor 626, respectively, in an appropriate format. Reading digitized video data from a PCI bus and displaying the video data on a monitor screen using graphic adapter cards are well known to those of skill in the art. In addition, the processes of controlling the transfer of signals along a PCI bus using a CPU is well known to those of skill in the art.

USB interface 172 provides set up data to timing and control logic 171 (see FIG. 1). Users can input signals into the system that indicate how pixel signals are read out of each CCD. This is used by logic 171 to tailor signals HST and VST for each CCD sensor so that the pixel signals are stored in memory circuits 535 and 536 in a configuration that is independent of how pixel signals are read out of the CCD sensor, as discussed above.

USB interface 172 also provides a means to remotely program gain values in programmable gain amp 404, offsets, mode control constants and set-up/calibration values that may be required. It makes camera 100 programmable via a PC, etc.

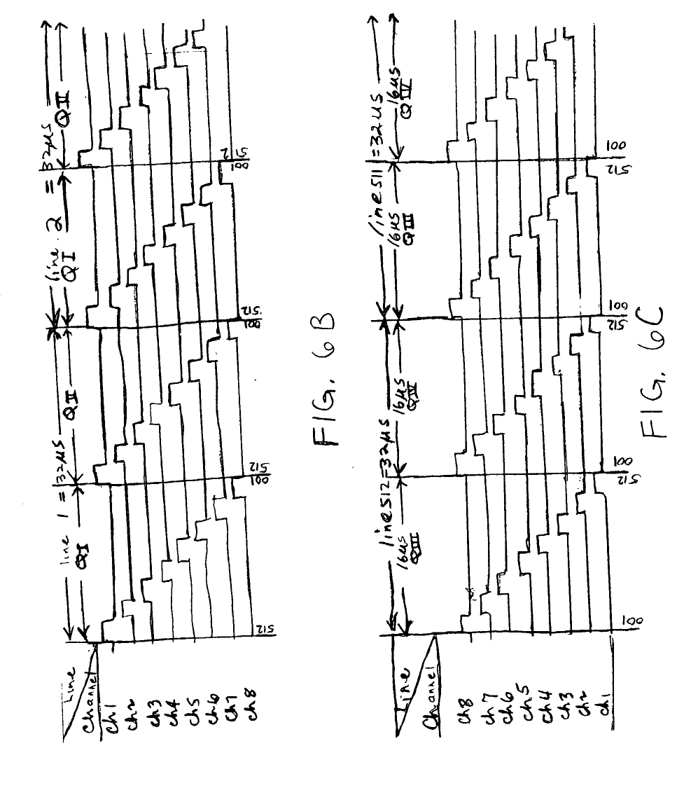

FIG. 8 illustrates an example of a CCD array that can be used with the cameras of the present invention. Four CCDs 101-104 are arranged in a 2×2 array. Other CCD array patterns may be chosen. For example, a CCD array may comprise a 2×3 array, a 2×4 array, a 4×4 array, a 2×6 array, etc.

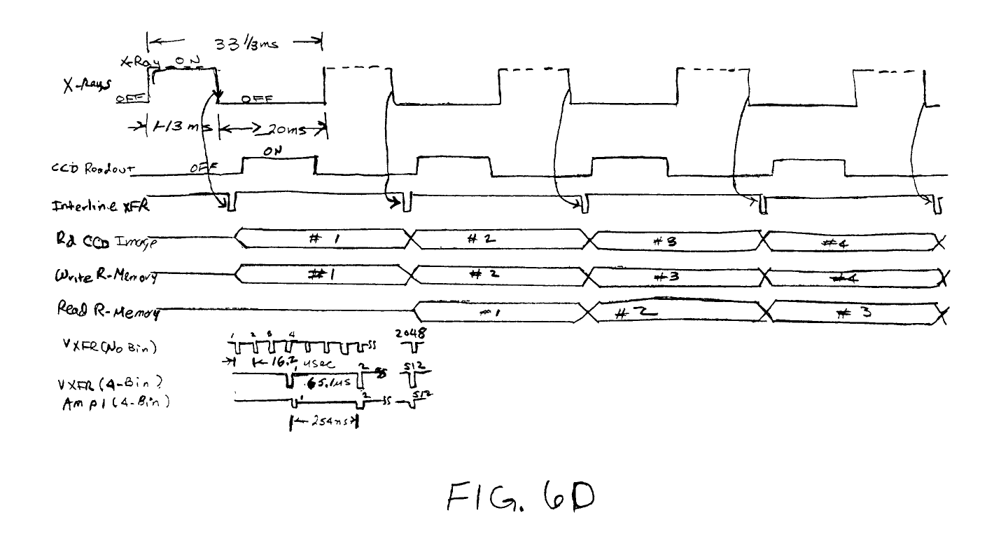

FIG. 9 illustrates a charge coupled device (CCD) 218 and the integrated circuitry used to transfer charge out of CCD 218. CCD 218 includes a plurality of pixels 221 and adjacent storage sites. Pixels 221 are arranged in a plurality of rows and columns. For example, a CCD may include 2048 rows and 2048 columns of pixels and adjacent storage sites (horizontal shift registers).

The circuitry shown in FIG. 9 includesa plurality of parallel transmission gates 212, vertical summing wells 219, horizontal shift registers 213, transmission gate 214, horizontal summing well 215, transmission gate 216, and buffer circuit 217. Each transmission gate 212 is coupled to one of the columns of pixels and to one of horizontal shift registers 213.

The pixels in a charge coupled device may be divided into a number of channels. For example, a CCD with 2048 columns of pixels may be divided into 8 channels, with 256 columns of pixels associated with each of the 8 channels.

One horizontal shift register is typically coupled to receive signals from only one channel of pixels in the CCD. For example, a CCD with 2048 columns of pixels may have 8 channels and 8 horizontal shift registers, wherein each horizontal shift register is coupled to receive signals from 256 columns of pixels. In the example of FIG. 9, horizontal shift register 213 is coupled to 24 columns of pixels in CCD 218 through transmission gates 212.

When electromagnetic radiation in a range of wavelengths impinges upon pixels 221, pixel signals representing image data are formed in semiconductor regions associated with the pixels. Vertical shift registers (not shown) associated with each column of pixels are used to transfer the pixel signals out of CCD 218 and into vertical summing wells 219.

The opening and closing of transmission gates 212 are controlled by one or more clock signals. Transmission gates 212 allow pixel signals in the last row 222 of pixels to be transferred to vertical summing wells 219. At the same time, the pixel signals in the second to last row 223 of pixels are transferred to row 222 using the vertical shift registers. The charge signals in all of the other pixels are also transferred to the next row using the vertical shift registers.

The pixel signals stored in row 222 that are originally from row 223 are then transferred to vertical summing wells 219, and the pixel signals in the other rows shift down one row.

More than one row of pixel signals may be summed together in an analog fashion in vertical summing wells 219. This technique is called binning. For example, pixel signals originally from row 223 may be summed with charge signals originally from row 222 in vertical summing wells 219. Alternatively, signals from multiple rows of pixels can be summed together in horizontal shift registers (HSR) 213. Each of the pixel signals from row 223 are added to a pixel signal from row 222 that is in the same column.

Alternatively, pixel signals from three, four, or more rows of pixels can be summed together in vertical summing wells 219 or HSR 213. Each pixel signal is added to pixel signals from other rows in the same column of pixels. If vertical summing wells 219 are used, the summed pixel signals are subsequently stored in HSR 213.

The summed charge signals are then shifted out of HSR 213 into horizontal summing well (SW) 215. Transmission gate 214 controls how many columns of pixel signals are transferred into horizontal summing well 215. The opening and closing of transmission gate 214 is controlled by one or more clock signals. Clock signals also control the shifting of charge signals across horizontal shift registers 213.

Pixel signals from multiple columns of pixels can be added together in summing well 215. This method is also part of the binning technique mentioned above. Pixel signals from multiple columns of pixels can be added together in an analog fashion in summing well 215.

For example, transmission gate 214 can allow pixel signals from four columns of pixels to be transferred into summing gate 215. The pixel signals from the four columns of pixels are added together in an analog fashion in summing well 215. When transmission gate 216 opens, the summed charge signal in summing well 215 is buffered by buffer 217 and transferred to additional circuitry for further image processing.

In a 4×4 binning technique, signals from four rows of pixels are added together in HSR 213 or summing wells 219, and the summed signals from four columns of pixels are added together in summing well 215. Thus, signals from a total of 16 pixels (in 4 rows and 4 columns) are summed together in summing well 215 and then buffered by buffer 217. In a 2×2 binning technique, charge signals from 4 pixels (2 rows and 2 columns) are summed together in summing well 215.

Binning charge signals from multiple pixels in a CCD provides a way to control the resolution, to read-out images faster, to increase the strength of weak signals, and to increase the signal-to-noise ratio of the CCD output signals. However, these advantages come at the expense of reduced image resolution.

Signals from the pixels can also be binned to achieve different resolutions on different areas of a CCD. For example, 1×1 binning can be applied to signals from pixels in the center of the CCD, while 4×4 binning is applied to signals near the edges of the CCD. In another embodiment, the number of pixel signals in a CCD channel can be selected to be a multiple of the number of pixels signals summed in each bin. For example, if a channel has 1020 columns and 1020 rows of pixels, then 1×1, 2×2, 3×3, 4×4, 5×5, and 6×6 binning can be applied without having extra pixel signals left over at the end of a channel.

In a further embodiment, the number of pixels in a CCD channel does not need to be a multiple of the number of pixel signals summed in each bin. In this embodiment, pixel signals left over at the end of each channel are added to pixel signals from an adjacent channel to complete the bin. For example, for CCD channel with 256 columns of pixels, 1 pixel signals is left over at the end of the first channel using 3×3 binning. This extra pixel signal can be added to the first two columns of pixel signals in the next adjacent channel. Further details of a Charge Coupled Device Sensor with Variable Resolution are discussed in U.S. patent application Ser. No. ______ (Attorney Docket Number 013843-003700US), to Camara, filed concurrently herewith, which is incorporated by reference herein.

Referring again to FIG. 8, if the edges adjacent to the active area of the charge coupled devices (CCDs) touch each other when placed in an M×N array, the CCDs may become damaged. Also, the imaging area does not extend to edge of CCD. Therefore, a spatial gap is formed between the edges of each CCD in an array as shown in FIG. 8. For example, spatial gap 105 is formed between the edges of CCDs 101 and 102.

However, when an image is formed from light impinging on a M×N CCD array with gaps, the light that falls between the CCDs into the gaps is lost. As a result, a portion of the image is lost, and the image formed from the CCD array appears with seams or gaps between the CCD tiles. The seam that forms between tiles in a CCD array can be reduced or eliminated by using the techniques of the present invention. These techniques are now discussed in further detail.

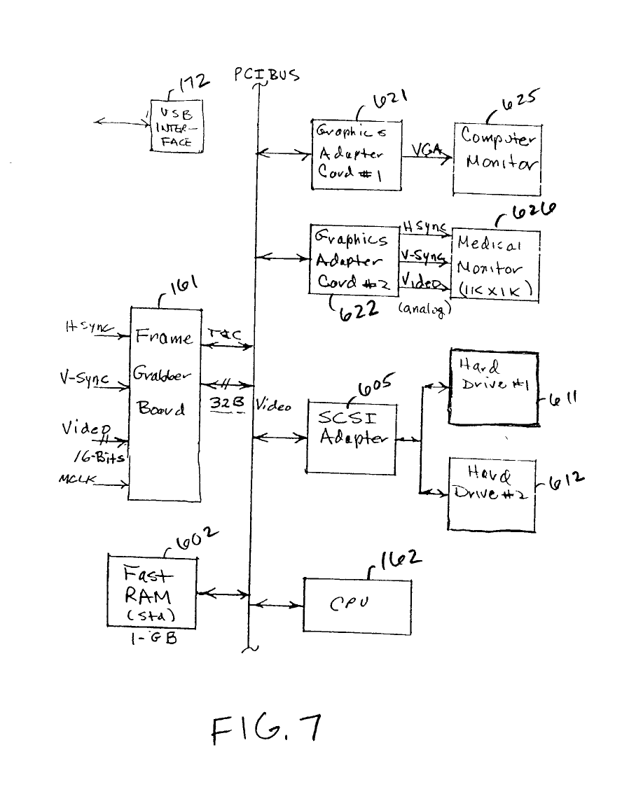

FIG. 10 illustrates a cross section of a first embodiment of a seamless imager 110 in accordance with the present invention. Imager 110 includes charge-coupled devices 126 and 125. Each of charge coupled devices (CCDs) 126 and 125 includes a plurality of rows and columns of pixels. Only one row of pixels is shown in FIG. 10 for simplicity. The pixels are assigned integer numbers from 0 to 8 in FIG. 10. Charge coupled devices 126 and 125 are placed in headers 127 and 128, respectively, for support. Headers 127 and 128 may comprise ceramic or other material.

Optical fiber array 148 is placed above CCD 126 and a portion of header 127, and optical fiber array 149 is placed above CCD 125 and a portion of header 128, as shown in FIG. 10. Arrays 148 and 149 also protect CCDs 126 and 125 from impinging X-Rays that might damage the CCDs. Scintillator 119 is placed over optical fiber arrays 148 and 149.

Radiation (e.g., X-Rays) from an object impinges upon the upper surface of scintillator 119. Scintillator 119 converts the radiation into electromagnetic radiation with a longer wavelength. For example, scintillator 119 may shift the wavelength of X-Rays into the visible spectrum, the ultra-violet spectrum, or the infrared spectrum.

The edges of arrays 148 and 149 do not touch each other. If arrays 148 and 149 contact each other, the optical fibers could chip. Therefore, there is a small air gap or shim between the inner edges of arrays 148 and 149, as shown in FIG. 10.

Optical fiber array 148 includes numerous parallel optical fibers 115 that extend from one surface of the array to another. Optical fiber array 149 also includes numerous parallel optical fibers 116 that extend from one surface the of the array to another. Optical fibers 115 are tilted at an angle that is less than 90° with respect to the plane of CCD 126, and optical fibers 116 are tilted at an angle that is less than 90° with respect to the plane of CCD 125, as shown in FIG. 10.

Radiation from an x-rayed object impinges upon the upper surface of a scintillator panel 119. Scintillator 119 may comprise any type of scintillator material (e.g., cesium iodide). Scintillator 119 coverts the radiation into longer wavelength electromagnetic radiation. For example, the electromagnetic radiation from scintillator 119 may comprise visible light, infrared light, and/or ultraviolet light. In a further embodiment, scintillator 119 may be left out, and light from on object can directly enter the optical fibers (instead of using x-rays). In this embodiment, the scintillator is not needed to convert the incoming light to a longer wavelength.

The electromagnetic radiation from scintillator 119 enters optical fibers 115 and 116. Optical fibers 115 and 116 conduct electromagnetic radiation (e.g., light). The electromagnetic radiation travels through optical fibers 115 and 116 to charge coupled devices 126 and 125.

One or more of optical fibers 115 and 116 falls on each pixel in CCDs 126 and 125. Pixels in the CCDs are sensitive to particular wavelengths of electromagnetic radiation. For example, CCDs may be sensitive to visible light, infrared light, and/or ultraviolet light. The pixels sense electromagnetic radiation in a range of wavelengths provided by the optical fibers. A pixel outputs an electrical signal in response to the intensity of electromagnetic radiation received through the optical fiber. The term light as used herein is used for simplicity and is not intended to be limited to visible light.

After exposure, signals from the pixels are temporarily stored in vertical shift register elements in the semiconductor wafer. CCDs of the present invention may, for example, comprise interline transfer CCDs. Interline transfer CCDs have columns of vertical shift registers that are interleaved in between the columns of pixels. Each column of pixels is adjacent to a column of vertical shift registers. The signals from the pixels do not have to travel far to be stored in the vertical shift registers in interline transfer CCDs. This configuration helps to increase the data transfer rate of CCDs. Further details of Large Area, Fast Frame Rate Charge Coupled Devices are discussed in U.S. patent application Ser. No. ______ (Attorney Docket Number 013843-003200US), to Wen et al., filed concurrently herewith, which is incorporated by reference herein.

Subsequently, the pixel signals are read out from the CCD, processed and transmitted to the image reconstruction circuitry. The image reconstruction circuitry reconstructs the pixel signals into image data signals raster formatted to display a reproduction of the image on a display screen for viewing. Further details of exemplary image reconstruction circuitry are discussed in Image Reconstruction Techniques for Charge Coupled Devices, U.S. patent application Ser. No. ______ (Attorney Docket Number 013843-004200US) to Natale Tinnerino, filed concurrently herewith, which is incorporated by reference herein.

One end of optical fiber 117 in array 148 extends to the upper right corner of array 148. The light rays that enter optical fiber 117 from scintillator 119 reach pixel 4 in CCD 126. The light rays entering the optical fibers 115 that are to the left of fiber 117 in FIG. 10 reach pixels designated 4, 5, 6, 7, or higher in CCD 126. No useful light from scintillator 119 travels through optical fibers 115 that are to the right of optical fiber 117 in FIG. 10, because the ends of these optical fibers 115 are exposed along a side wall of fiber optic array block 148.

Similarly, no useful light from scintillator 119 travels through optical fibers 116 that are to the left of optical fiber 118 in FIG. 10. One edge of optical fiber 118 extends to the upper left corner of array 149. Light travels through optical fiber 118 from scintillator 119 to pixel 3 in CCD 125. The light traveling through optical fibers 116 that are to the right of fiber 118 reaches pixels designated 3, 4, 5, 6, 7, or higher in CCD 125.

By angling optical fibers 115 and 116 within arrays 148 and 149 as shown in FIG. 10, the seams in the image caused by the gaps between the CCDs (such as gap 105) are significantly narrowed. The optical fibers to the left of fiber 117 in array 148 and to the right of fiber 118 in array 149 capture light from scintillator 119 above the spatial gap between CCDs 126 and 125. The light captured by the optical fibers is sensed by the CCD sensors.

The light exiting scintillator 119 in the gap between CCDs 126 and 125 would not be sensed by the CCDs without arrays 148 and 149. Only the light that exits scintillator 119 in the gap between fiber optic arrays 148 and 149 is not sensed by CCD sensors 126 and 125. Thus, the seam that shows up in the image outputted from CCD sensors 126 and 125 is significantly reduced, because much less of the light falling between the CCD sensors is lost in imager 110.

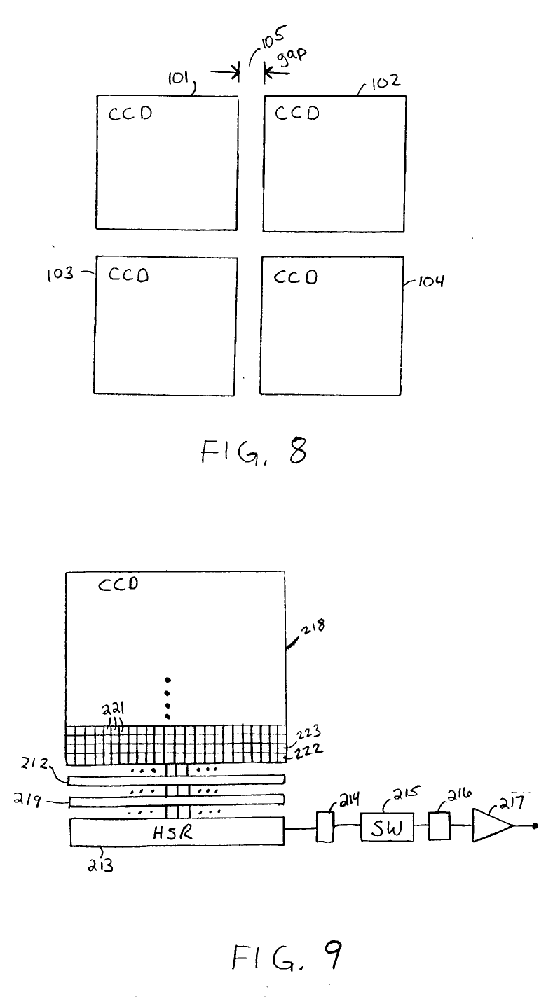

FIG. 11 illustrates a cross section of a second embodiment of a seamless CCD imager of the present invention. Scintillator 321 lies on top of fiber optical arrays 325 as shown in FIG. 11. Fiber optic arrays 325 are placed on top of CCD chips such as CCD 322. The CCD chips are attached to the headers such as header 323.

Fiber optic arrays 325 each contain a plurality of tapered optical fibers. Each optical fiber transmits electromagnetic radiation from scintillator 321 one or more pixels in one of the CCDs.

The optical fibers in arrays 325 are not linear as in the embodiment of FIG. 11. The tapered optical fibers in the fiber optic arrays 325 fan out from the CCDs to scintillator 321. The optical fibers around the edges of the fiber optic arrays 325 bend away from a center axis of fiber optic arrays 325 above the surfaces of the charge coupled devices as shown in FIG. 11.

The fiber optic arrays 325 capture most of the light from scintillator 321 that falls into the spatial gaps between the CCDs, as with the previous embodiment. Therefore, fiber optic arrays 325 also substantially reduce the seams between CCDs that appear in an image formed from a CCD array.

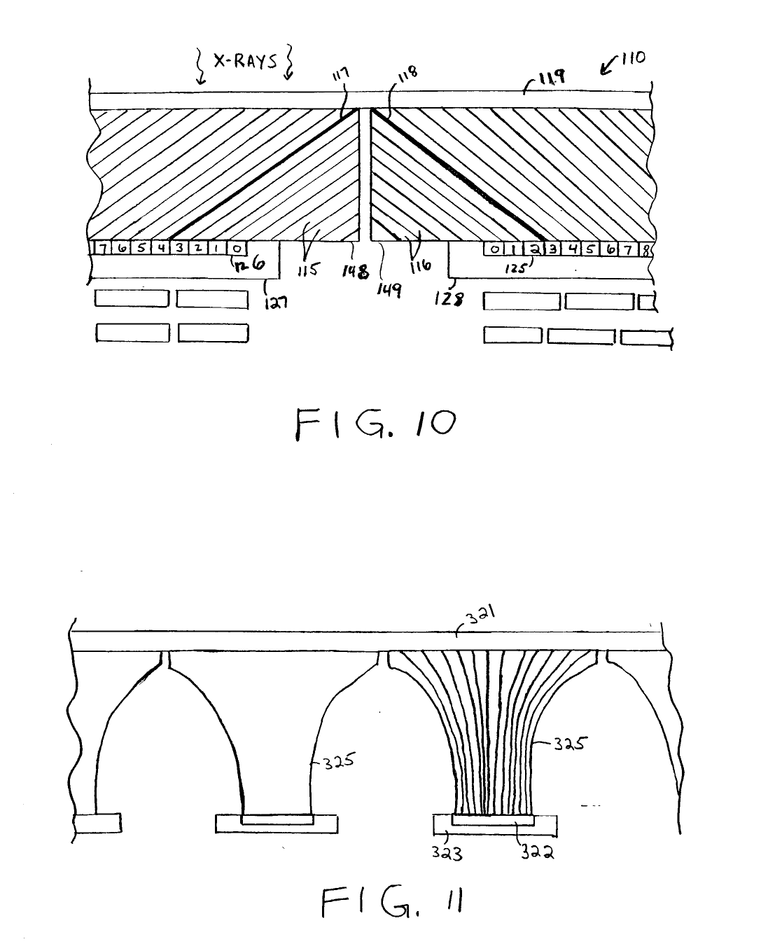

Image data can be extracted from cameras of the present invention using binning techniques. FIG. 12 illustrates an imaging device of the present invention that has a CCD 413 coupled to an array of optical fibers 411. Array 411 has a plurality of optical fibers including optical fiber 412. CCD 413 has a plurality of rows and columns of pixels. Only one row of pixels is shown in FIG. 12 for simplicity. Each pixel in the row is assigned an integer number in FIG. 12. CCD 413 is attached to header 415. The scintillator is not shown in FIG. 12.

The pixels in CCD 413 are grouped into a plurality of channels. Each channel contains a fixed number of pixel columns. For example, in the embodiment of FIG. 12, channels A, B, and C each contain 16 columns of pixels.

The blocks in row 430 are representations of bins that each hold 4 columns of pixels summed together in summing well 215 (e.g., using 4×4 binning). The 16 columns of pixels in each channel may be grouped into four bins with 4 columns of pixels summed together in each bin. The blocks in row 430 represent four bins in each channel, with 4 pixel columns in each bin.

One end of optical fiber 412 is exposed at the upper right corner of array 411 as shown in FIG. 12. Fiber 412 is the last fiber that is exposed at the upper surface of array 411 on its right side. Fiber 412 extends down to the edge of pixel 5 in CCD 413. Only optical fibers that are to the left of fiber 412 (including fiber 412) transmit useful light from the scintillator. Optical fibers that are to the right of fiber 412 in FIG. 12 do not transmit useful light from the scintillator.

Because useful light from the scintillator does not reach pixels 0, 1, 2, 3, and 4 in CCD 413, there is no image data in the first bin 420 of pixels, which includes pixels 0-3. In addition, the image data in bin 429 is distorted, because bin 429 includes pixel 4, which also does not have any image data.

Binning techniques can be modified according to the principles of the present invention to eliminate bins that contain no image data. For example, in the device shown in FIG. 12, bins containing charge signals from pixels 0-4 can be eliminated, without eliminating charge signals from pixels 5 and up.

The signal from pixel 0 can be clocked into and out of summing well 215 without being added to charge from any of the other columns of pixels. Therefore, the charge signal to pixel 0 is placed in a bin 441 by itself. The signal from bin 441 is discarded by other circuitry in the imager and is not used in the active image.

The four charge signals received from pixels 1-4 are summed together in summing well 215 to form bin 442. Bin 442 does not contain any image data, because pixels 0-4 receive light from the side edge of fiber optic array 411. Therefore, circuitry in the imager discards the first two signals from bins 441 and 442 that are outputted by amplifier 217. These two signals are not used in the active image.

A small amount of light exiting the scintillator falls into the gap between the fiber optic arrays and does not get picked up by the CCD sensors. Therefore, a small amount of light from the image is lost when using the imager of FIGS. 10-11. This light loss appears as a small seam in the reconstructed image between the CCD tiles.

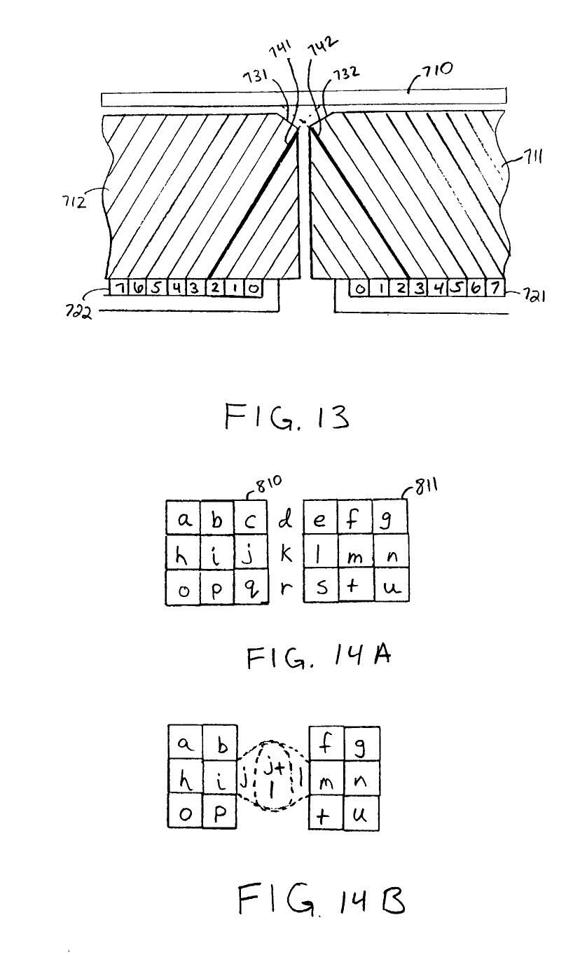

FIG. 14A illustrates a visualization of the light loss that occurs as a result of the gap between the fiber optic arrays. Squares labeled a through u in FIG. 14A represent packets of light that exit the scintillator. The packets of light that fall on one of squares 810 or 811 are sensed by the CCDs. These packets of light are used to generate the final image.

However, packets of light d, k, and r fall between the CCDs in the gap between the fiber optic arrays. These packets of light are not used to generate the final image, because they are not picked up by the optical fibers. In another embodiment of the present invention, the edges of the fiber optic arrays discussed above can be beveled to allow the light produced at or near the gap between the fiber optic arrays to be collected.

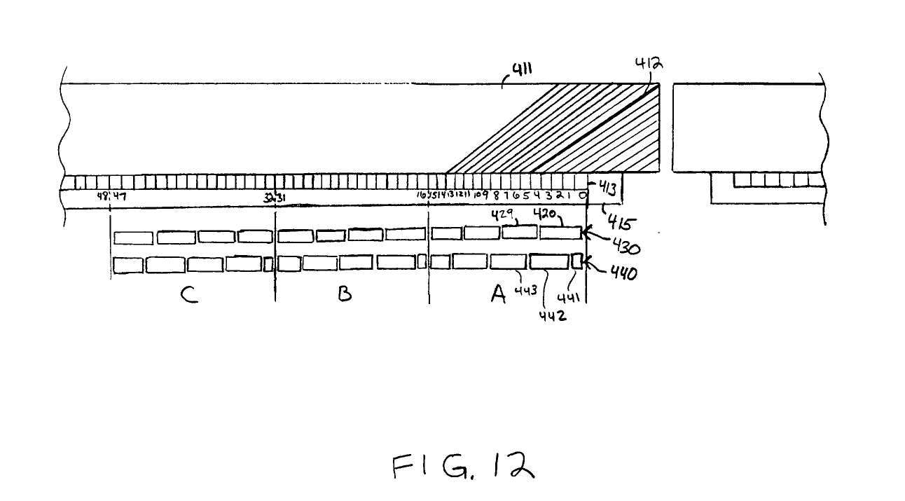

FIG. 13 illustrates this embodiment of the present invention. FIG. 13 illustrates an imaging device that includes scintillator 710, fiber optic arrays 711-712, and CCDs 721-722. Fiber optic array 711 has a beveled corner 732, and fiber optic array 712 has a beveled corner 731. The optical fibers in arrays 711-712 that are exposed in beveled areas 731-732 see the light in the gap at an angle and map to imaging pixels in CCD sensors 721-722.

Light exiting scintillator 710 (including light from the gap area) enters optical fibers in arrays 711-712 at beveled edges 731-732 and travels through the optical fibers to pixels in CCDs 721-722. Optical fibers 741 and 742 mark the boundary between the optical fibers that receive light from scintillator 710 and those that do not. By beveling the edges of arrays 711 and 712, more light from the scintillator that falls in the gap is sensed by CCDs 721 and 722, than would be the case without beveled edges 731-732. Only pixels 0-2 in CCDs 721 and 722 do not receive light from scintillator 710.

Pixels in CCDs 721-722 receive light in the gap area from scintillator 710 with beveled edges 731-732. For example, without beveled edge 731, light in the gap from scintillator 710 would not be seen. With beveled edge 731, pixel 3 is fully illuminated with light in the gap from scintillator 710. Therefore, the embodiment of FIG. 13 can sense more light in between the fiber optic arrays than the embodiments of FIGS. 10-11, enabling the sensors to generate a more complete image.

The light that falls into the gap between arrays 711 and 712 is lost and is not normally picked up by CCDs 721-722. However, beveled edges 731-732 pick up more light than the edge of array 411. The light that falls on the inner edges of beveled edges 731-732 near the gap between arrays 711-712 overlaps in the generated image.

FIG. 14B illustrates a visualization of that overlap. The light packets j and l fall on beveled edges 731-732 and travel to CCDs 721-722 through optical fibers in arrays 711-712. Light packets j and l are sensed by pixels 3 in CCDs 722 and 721. Because light packets j and l fall on beveled edges 731-732, which are slanted at an angle, the sharpness of the image reproduced by pixels 3 is reduced. The reproduction of light packets j and l overlap as shown in FIG. 14B.

While some sharpness in the image at the seams between CCDs may be lost, the device of FIG. 13 provides a continuous image without any blind gaps or seams between the CCDs. A continuous image that does not have any seams is typically more desirable than an image with seams. The embodiment of FIG. 13 may also be applied to sensors with optical fibers that are perpendicular to the plane of the CCD sensors.

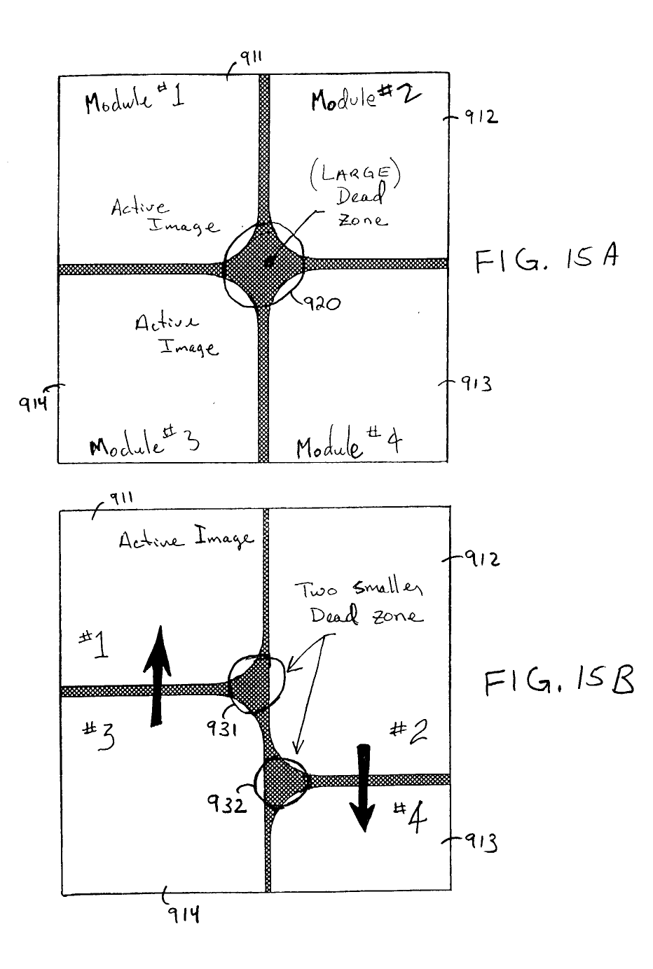

FIGS. 15A-15B illustrate another embodiment of the present invention. FIG. 15A illustrates a top down view of a portion of a tiled array of fiber optic arrays 911-914. Each of the fiber optic arrays is positioned in a quadrant of the array, with a gap between each fiber optic array. Because fiber optic arrays typically have rounded corners as shown in FIG. 15A, a large dead zone 920 is formed in the middle of the array. Dead zone 920 is surrounded by the edges of four fiber optic arrays 911-914.

The light that falls into dead zone 920 is not sensed by any of the CCDs associated with fiber optic arrays 911-914. Therefore, a significant portion of the image is lost in the image generation process because of the large size of zone 920. The final generated image appears with a large hole corresponding to the location of zone 920. A large image hole such as the hole caused by zone 920 is very difficult to electronically correct.

FIG. 15B illustrates a technique of the present invention that reduces the size of dead zone 920. Fiber optic arrays 912 and 913 are shifted down, and fiber optic arrays 911 and 914 are shifted up so that the size of dead zone 920 is substantially reduced. Fiber optic arrays 911-914 are shifted enough so that dead zone 920 is split into two smaller dead zones 931 and 932. Dead zones 931-932 are half the size of dead zone 920. Dead zone 931 is only surrounded by fiber optic arrays 911, 912, and 914. Dead zone 932 is only surrounded by fiber optic arrays 914, 913, and 912.

Dead zones 931-932 also cause holes in the final generated image. However, the holes caused by dead zones 931-932 are half the size of the hole caused by dead zone 920. The small image holes caused by zones 931 and 932 are easier to correct using well know post-sensing electronic techniques.

In the embodiment of FIG. 15B, the CCD sensors underneath the shifted fiber optic arrays may remain in a rectangular configuration as shown in FIG. 8. In a further embodiment, the CCD sensors underlying the fiber optic arrays can be shifted in the same directions as the fiber optic arrays to reduce dead zones between the CCDs. In this embodiment, the CCDs are positioned in the same configuration as the fiber optic arrays.

One difficulty in manufacturing an array of tiled charge coupled devices involves the alignment of the fiber optic arrays. If the upper surfaces of the fiber optic arrays are not aligned in a flat, even plane, any unevenness in the upper surfaces of the arrays can cause the reproduced image to be distorted. Therefore, the upper surfaces of the fiber optic arrays in a tiled CCD structure are preferably aligned in a flat, even plane. However, it can be a difficult and tedious process to align the upper surfaces of the fiber optic arrays or the upper surfaces of the CCDs optically. It can also be difficult to remove and to replace a damaged CCD chip in a tiled CCD array.

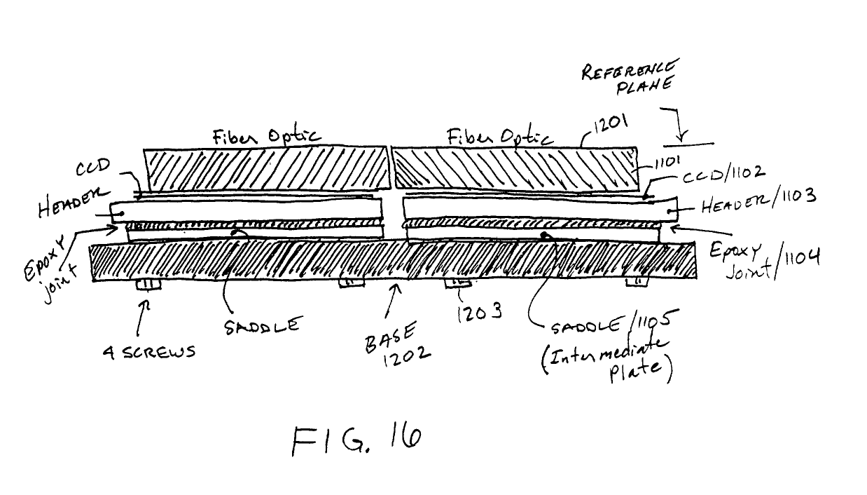

FIG. 16 illustrate an embodiment of the present invention that makes it possible to manufacture a tiled CCD structure so that the upper surfaces of the fiber optic arrays are aligned in a flat, even reference plane. FIG. 16 illustrates an array of CCDs that are formed with an even reference plane in accordance with this embodiment of the present invention. The CCD array shown in FIG. 16 includes charge coupled devices (CCDs) that are arranged in a 2×3 array. The CCDs 1102 (imaging chip) are shown in FIG. 16.

The CCDs in the array are each attached to a header (also called a carrier). CCD 1102 is attached to carrier 1103. A fiber optic array is attached to each CCD in the array (e.g., using clear epoxy). Fiber optic array (faceplate) 1101 is attached to CCD 1102 as shown in FIG. 16. The optical fibers in array 1101 may be angled to reduce the seams between CCD tiles as discussed above in the previous embodiments.

The assembly of FIG. 16 also includes a saddle 1105 that is attached to each carrier 1103 through an epoxy joint 1104. Each carrier 1103 has a connector (not shown) that connects to the output pins of the CCD chip 1102. The scintillator is not shown in FIG. 16. The saddles 11 05 are also referred to as intermediate plates.

By adding a fiber optic array to the top surface of each CCD in the array, the optical reference plane is shifted from the top surface of the CCDs to the top surface of the fiber optic arrays. Because the fibers in the fiber optical arrays project the image directly onto the CCD chips, the placement of the CCD chips does not effect the image quality. For example, the quality of the image is not adversely effected if the CCDs are tilted with respect to one another or are not aligned in the same plane.

The upper surface of each of the fiber optic arrays is aligned with respect to a reference plane (see FIG. 16). By aligning the fiber optic arrays with respect to the reference plane, the upper surfaces of the fiber optic arrays form a flat, even plane. The reference plane also removes any tilt between the upper surfaces of the fiber optic arrays.

For example, the upper surfaces 1201 of the fiber optic arrays 1101 (FIG. 16) can be placed face down on a surface that has a flat, even plane. This surface forms a common reference plane for the fiber optic arrays that keeps their upper surfaces 1201 on a flat, even plane. The upper surfaces of the CCDs (attached to the ceramic headers) are attached to the bottom surfaces of the fiber optic arrays.

The saddles 1105 are attached to a base unit 1202. For example, saddles 1105 can be screwed onto case 1202 using screws 1203. One saddle 1105 is screwed onto base 1202 for each CCD in the array.

Once the reference plane has been established for the CCDs and the fiber optic arrays, a layer of epoxy 1104 is applied evenly to the saddles 1105. The purpose of epoxy layer 1104 is to bond headers 1103 to saddles 1105. After epoxy layer 1104 is applied, base 1202 is inverted, and saddles 1105 are glued onto headers 1103.

The thickness of the epoxy layer 1104 can vary to accommodate any variation between the thickness and the planarity of the bottom surfaces of fiber optic arrays 1101. Once epoxy layer 1104 dries, the upper surfaces 1201 of the fiber optic arrays remain in a level, even plane, and the headers 1103 are securely bonded to the saddles 1105. The final structure is shown in FIG. 16.

A damaged CCD chip can be easily removed from the structure of FIG. 16, as will now be discussed. First, screws 1203 that attach to the damaged CCD chip are removed. The damaged CCD chip along with its corresponding fiber optic array and saddle are then carefully lifted off base 1202 and removed from the CCD array. Once the defective CCD has been removed, a new CCD can be easily installed.

To install the new CCD module, a new saddle is first screwed onto base 1202 where the old saddle was removed. Then, an even amount of epoxy is applied to the saddle. Spacers can be placed between saddles so that the replacement fiber optic array does not sink below the reference plane. For example, the epoxy can travel into the spaces between the saddles before it dries causing the fiber optic array to fall below the reference plane.

A new fiber optic array is attached to a new CCD and a new ceramic header. The new fiber optic array is then inverted so that its upper surface is placed on a reference plane. The base with the CCD array is then inverted, and the replacement saddle is gently placed on top of the new ceramic header. The upper surfaces 1201 of the old fiber optic arrays are placed on the same common reference plane as the new fiber optic array. When the epoxy hardens, the upper surface of the replacement fiber optic array aligns with the reference plane of the other fiber optic arrays in the assembly. The thickness of the epoxy layer varies to accommodate for any variations in the thickness and planarity of the replacement fiber optic array. Further details of the embodiments shown in FIGS. 8-16 are discussed in U.S. patent application Ser. No. ______ (Attorney Docket Number 013843-003600US), mentioned above.

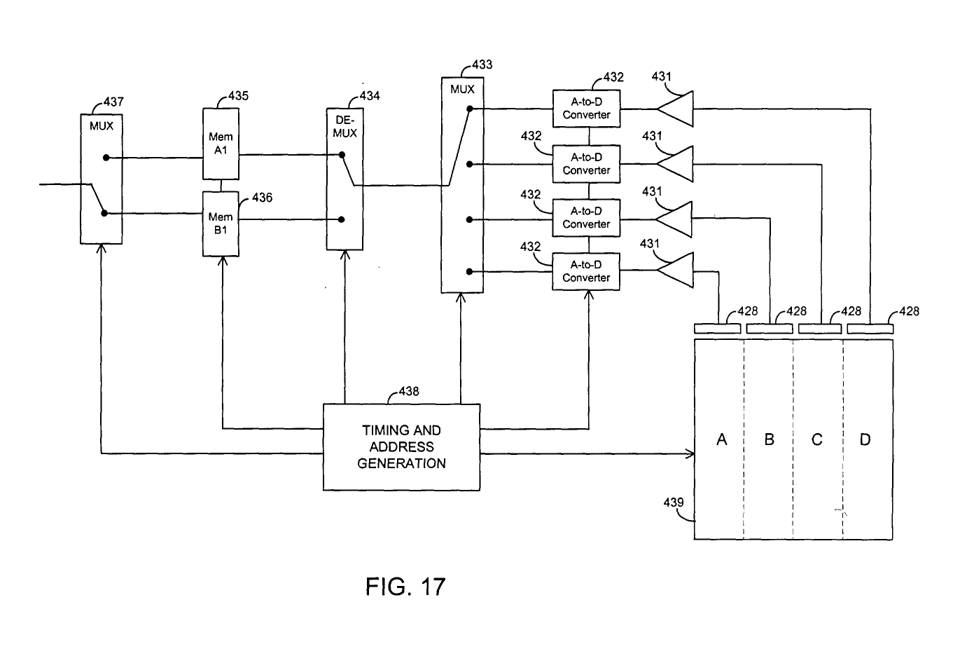

The pixels in a charge coupled device may be divided into a number of channels. For example, a CCD with 2048 columns of pixels may be divided into 8 channels, with 256 columns of pixels associated with each of the 8 channels. CCD 439 shown in FIG. 17 is divided into four channels A, B, C, and D.

Separate horizontal shift registers, summing wells, amplifiers, and A-to-D converters are used for each channel in a CCD. Each horizontal shift register is coupled to receive signals from pixels in only one channel of pixels in the CCD.

For example, circuit elements 428 correspond to circuit elements 212-17 and 219 in FIG. 9. A separate circuit 428 is coupled to each channel in CCD 439. Circuits 428 each receive signals from columns of pixels in the corresponding channel of CCD 439. The signals output by circuits 428 are amplified by corresponding ones of amplifiers 431 and converted to digital signals by corresponding ones of A-to-D converters 432.

Multiplexer 433 is used to join signals from pixels in all of the columns in CCD 439 into a single data stream at the output of multiplexer 433. De-multiplexer 434 then writes pixel signals in for one frame in memory circuit 435 and pixel signals for another frame in memory circuit 436. Multiplexer 437 reads signals out of one of memory circuits 435 or 436 while signals are written into the other memory circuit to increase the frame rate as discussed above.

Timing and address generation circuit 438 controls outputs a plurality of clock signals. The clock signals control the transfer of data through the horizontal shift registers and the transmission gates in circuits 428, A-to-D converters 432, multiplexer 433, demultiplexer 434, and multiplexer 437. Circuit 438 also outputs memory address signals that control the memory locations for the pixel signals as discussed above with respect to FIG. 5. The memory address signals from circuit 438 may cause pixel signals from CCD 439 to be re-oriented when they are stored in memory circuits 435 and 436. When the pixel signals are read out of memory circuits 435 and 436, they are ordered in a sequence that allows them to be easily displayed in the same orientation that the CCD 439 pixels sensed the image. Further details of the embodiment shown in FIG. 17 are discussed in U.S. patent application Ser. No. ______ (Attorney Docket Number 013843-004200US), mentioned above.

While the present invention has been described herein with reference to particular embodiments thereof, a latitude of modification, various changes, and substitutions are intended in the present invention. In some instances, features of the invention can be employed without a corresponding use of other features, without departing from the scope of the invention as set forth. Therefore, many modifications may be made to adapt a particular configuration or method disclosed, without departing from the essential scope and spirit of the present invention. It is intended that the invention not be limited to the particular embodiment disclosed, but that the invention will include all embodiments and equivalents falling within the scope of the claims.

What is claimed is:

1. A camera that provides signals that can be used to generate video, the camera comprising:
a scintillator;
a plurality of arrays comprising optical fibers that receive electromagnetic radiation from the scintillator;
a plurality of charge coupled devices that can continuously sense electromagnetic radiation received from the optical fibers, each charge coupled device being adjacent to at least one other charge coupled device;
registers that store signals generated by pixels in the charge coupled devices;
analog-to-digital converter circuits that covert the signals generated by the pixels into digital signals; and
memory circuits that store the digital signals, wherein a first set of the digital signals are read out of a first set of the memory circuits and used to generate a first video frame, while a second set of the digital signals indicative of a second video frame are written into a second set of the memory circuits.

2. The camera of claim 1 wherein the scintillator converts x-rays to visible light, and the plurality of charge coupled devices continuously sense visible light received from the optical fibers.

3. The camera of claim 1 wherein scintillator converts x-rays to ultraviolet light, and the plurality of charge coupled devices continuously sense ultraviolet light received from the optical fibers.

4. The camera of claim 1 further comprising:
a frame grabber that receives the digital signals from the memory circuits and provides the video data.

5. The camera of claim 4 wherein the frame grabber provides the video data to a graphics adapter card via a PCI bus, the graphics adapter card providing video signals to a display monitor for displaying the image frames.

6. The camera of claim 1 wherein the charge coupled devices are interline transfer charge coupled devices.

7. The camera of claim 1 further comprising:
amplifier circuits that amplify output signals of the registers and provide amplified signals to the digital-to-analog converters.

8. The camera of claim 1 wherein the digital signals are written into memory cells in the first and the second sets of memory circuits in configurations that are independent of the direction that the signals generated by the pixels are read out of the charge coupled devices.

9. The camera of claim 8 further comprising write address generation circuits associated with each of the charge coupled devices that generate write address signals in response to the read address signals, the write address signals determine the order that the digitized signals are written into the first and the second memory circuits.

10. The camera of claim 1 wherein the digital signals are written into memory cells in the first and the second sets of memory circuits in configurations that are dependent upon the direction that the signals generated by the pixels are read out of the charge coupled devices, and
wherein the digital signals are read out of the memory cells in the first and the second sets of memory circuits in configurations that are independent of the direction that the signals generated by the pixels are read out of the charge coupled devices.

11. The camera of claim 1 wherein the pixels in each of the charge coupled devices are separated into channels, and the signals generated by the pixels in each of the channels are stored a separate set of horizontal shift registers, a separate set of the analog-to-digital converters, and a separate set of the memory circuits.

12. The camera of claim 11 wherein signals generated in more than one row of the pixels are summed together and signals generated in more than one column of the pixels are summed together.

13. The camera of claim 12 wherein the camera comprises four charge coupled devices arranged in a 2×2 array, each of the charge coupled devices having at least eight channels.

14. A method for generating signals that can be used to display video frames in near real-time, the method comprising:
shifting the wavelength of radiation using a scintillator;
providing electromagnetic radiation to an array of charge coupled devices using optical fibers;
generating image signals from pixels in the charge coupled devices;
storing the image signals in registers;
converting the image signals to digital signals; and
writing a first subset of the digital signals corresponding to a first video frame into a first set of memory circuits, while a second subset of the digital signals corresponding to a second video frame are read out of a second set of memory circuits.

15. The method of claim 14 wherein the charge coupled devices are sensitive to visible light.

16. The method of claim 14 further comprising:
amplifying the image signals to provide amplified image signals, and providing the amplified image signals to analog-to-digital converters that provide the digital signals.

17. The method of claim 14 wherein the charge coupled devices comprise four charge coupled devices arranged in a 2×2 array, and each of the charge coupled devices has four or more channels.

18. The method of claim 14 wherein the charge coupled devices comprise interline transfer charge coupled devices.

19. The method of claim 14 further comprising:
summing the image signals from a selected number of rows and a selected number of columns of the pixels to provide summed signals, wherein the summed signals are amplified to provide the amplified image signals.

20. The method of claim 14 further comprising:
reading the first subset of the digital signals corresponding to the first video frame out of the first set of memory circuits, while a third subset of the digital signals corresponding to a third video frame are written into the second set of memory circuits.

21. The method of claim 19 wherein the digital signals are written into memory cells within the memory circuits in configurations that are independent of the direction that the image signals were read out of the charge coupled devices.

22. The method of claim 14 wherein the digital signals are read out of memory cells within the first and second sets of memory circuits in an order that is independent of the direction that the image signals were read out of the charge coupled devices.

23. The method of claim 22 wherein the digital signals are written into the memory cells in configurations that are dependent upon the direction that the image signals were read out of the charge coupled devices.

24. The method of claim 14 wherein each of the charge coupled devices are supported by a carrier, each of the carriers are attached to a saddle, and the saddles are attached to a base.

25. The method of claim 24 wherein arrays of the optical fibers associated with each of the charge coupled devices bow away from the center axis of the associated charge coupled device such that some of the optical fibers absorb light falling in gaps between the charge coupled devices in the array.

26. The method of claim 14 wherein the first set and the second set of the memory circuits comprise dedicated memory circuits, each of the dedicated memory circuits only stores signals from one of the charge coupled devices.

27. The method of claim 14 further comprising:
providing the digital signals to a frame grabber that outputs video data.
